(19) United States
(12) Patent Application Publication
(10) Pub. No.: US 2024/0188268 A1
(43) Pub. Date: Jun. 6, 2024

(54) COMPONENT MOUNTING MACHINE AND BACKUP PIN HOLDING METHOD

(71) Applicant: FUJI CORPORATION, Chiryu (JP)

(72) Inventors: Akihiro SENGA, Okazaki-shi (JP); Takayuki MIZUNO, Okazaki-shi (JP)

(73) Assignee: FUJI CORPORATION, Chiryu (JP)

(21) Appl. No.: 18/576,147

(22) PCT Filed: Jul. 12, 2021
(86) PCT No.: PCT/JP2021/026157

§ 371 Date: Jan. 3, 2024

(51) Int. Cl. H05K 13/00; H05K 13/04

(52) U.S. Cl. CPC H05K 13/0061; H05K 13/0409; H05K 13/041

(57) ABSTRACT

A component mounter includes a head capable of picking a component, a board conveyance device that conveys a board, a backup device that backs up the board from a rear surface by using a backup pin, and an accommodation base on which the backup pin is placed. The backup device includes the backup pin and a backup plate having an installation surface on which the backup pin is installed and a through-hole penetrating the backup plate vertically such that the backup pin can be inserted. The accommodation base is disposed to be located under the through-hole, and the backup pin inserted through the through-hole is placed thereon.

### TECHNICAL FIELD

The present description discloses a component mounter and a backup pin accommodation method.

### BACKGROUND ART

Conventionally, there is known a component mounter that mounts a component on a board and includes a board conveyance device for conveying the board and a backup device for backing up, from a rear surface, the board conveyed by backup pins arranged on a backup plate. For example, Patent Literature 1 discloses a backup jig that is used in a backup device, attaches multiple backup pins to a backup plate, and collects the multiple backup pins from the backup plate to which the multiple backup pins are attached. The backup jig includes a jig plate that has multiple holes, each of the multiple holes causing multiple backup pins to be attached and detached, and a holding device that switches between a holding state where the backup pins are held in the multiple holes and a release state where the multiple backup pins inserted through the multiple holes are released. The backup jig is conveyed in the same manner as the board and comprehensively collects the multiple backup pins from the backup plate or comprehensively attaches the multiple backup pins to the backup plate.

### PATENT LITERATURE

Patent Literature 1: JP-A-2017-143161

### BRIEF SUMMARY

### Technical Problem

Patent Literature 1 describes collecting and attaching multiple backup pins to a backup plate by using a backup jig, but does not refer to accommodating unused backup pins in a backup device.

A main object of the present disclosure is to enable unused backup pins to be accommodated in a backup device while preventing an increase in size of the backup device.

### Solution to Problem

The present disclosure employs the following means in order to achieve the main object described above.

A component mounter of the present disclosure is
a component mounter that mounts a component on a board, and includes
a head capable of picking the component,
a board conveyance device that conveys the board,
a backup device including a backup pin and a backup plate having an installation surface on which the backup pin is installed and a through-hole penetrating the backup plate vertically such that the backup pin can be inserted, and backing up the board conveyed by the board conveyance device from a rear surface by using the backup pin installed on the installation surface, and
an accommodation base which is disposed to be located under the through-hole and on which the backup pin inserted through the through-hole is placed.

The component mounter of the present disclosure includes a backup device that includes a backup pin and a backup plate including an installation surface on which the backup pin is installed, and backs up a board from a rear surface by using the backup pin installed on the installation surface. The backup plate further includes a through-hole penetrating vertically. An accommodation base is disposed under the through-hole, and the backup pin inserted through the through-hole is placed on the accommodation base. Accordingly, since the backup pin can be accommodated under the backup plate, it is not necessary to secure a dedicated space for accommodating the backup pin. As a result, unused backup pins can be accommodated in the backup device while preventing an increase in size of the backup device.

### BRIEF DESCRIPTION OF DRAWINGS

FIG. 1 is a schematic configuration view of a component mounter of the present embodiment.

FIG. 2 is a block diagram illustrating an electrical coupling relationship of a component mounter.

FIG. 3 is a schematic configuration view of a board conveyance device and a backup device.

FIG. 4 is a schematic configuration view of a backup pin.

FIG. 5 is a schematic configuration view of a head.

FIG. 6A is a schematic configuration view of a suction nozzle.

FIG. 6B is a schematic configuration view of a picker nozzle.

FIG. 7 is a schematic configuration view of a backup pin stocker.

FIG. 8A is a view illustrating a positional relationship between a backup pin on an accommodation base and a backup plate when the accommodation base is at a lifting end.

FIG. 8B is a view illustrating a positional relationship between a backup pin on an accommodation base and a backup plate when the accommodation base is at a lowering end.

FIG. 9 is a flowchart illustrating an example of a first-lane backup pin installation process.

FIG. 10 is a flowchart illustrating an example of a second-lane backup pin installation process.

FIG. 11A is a view illustrating a state where a backup pin is installed in a second lane.

FIG. 11B is a view illustrating a state where a backup pin is installed in a second lane.

FIG. 11C is a view illustrating a state where a backup pin is installed in a second lane.

FIG. 11D is a diagram illustrating a state where the backup pin is installed in a second lane.

FIG. 11E is a diagram illustrating a state where the backup pin is installed in a second lane.

FIG. 12 is a schematic configuration view of a component mounter according to another embodiment.

FIG. 13 is a schematic configuration view of a component mounter according to another embodiment.

### DESCRIPTION OF EMBODIMENTS

Next, an embodiment of the present disclosure will be described with reference to the drawings.

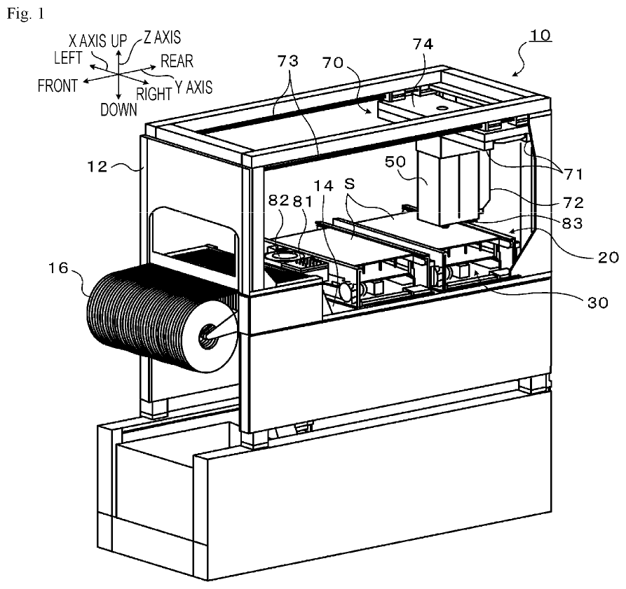

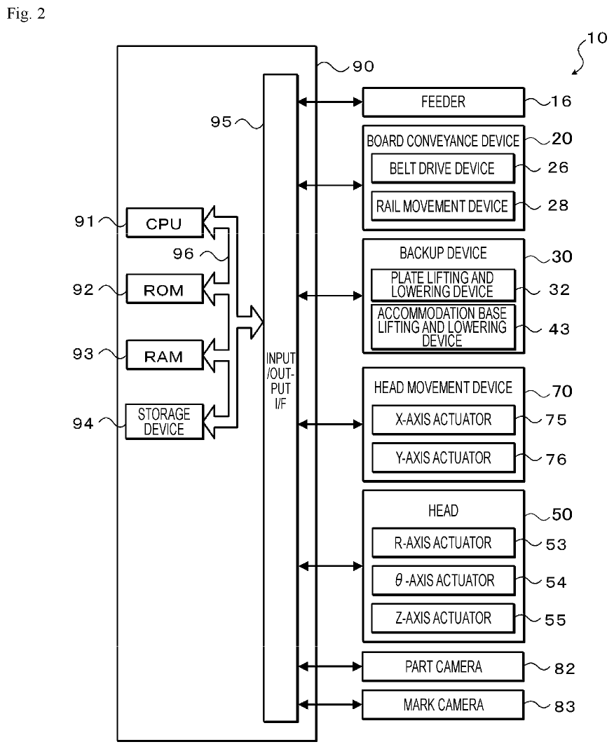

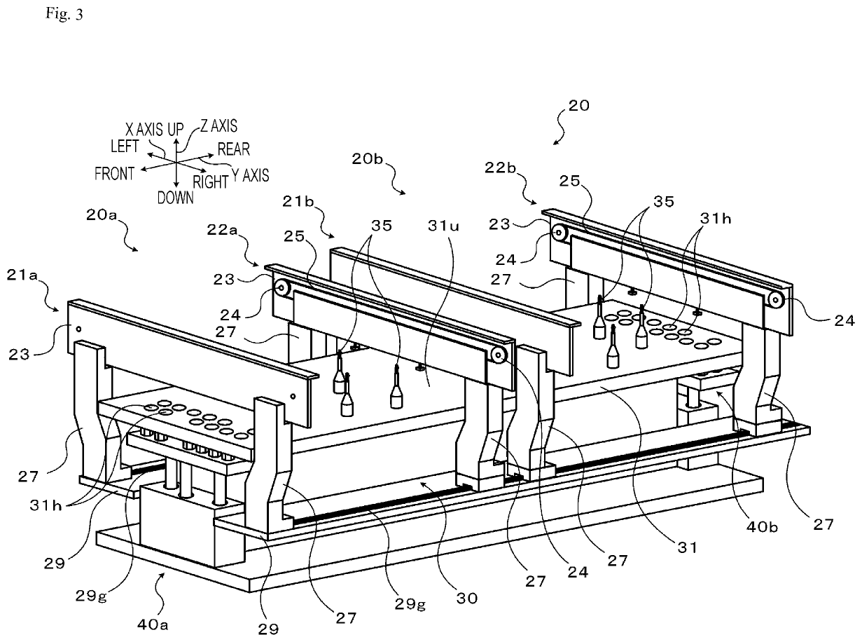

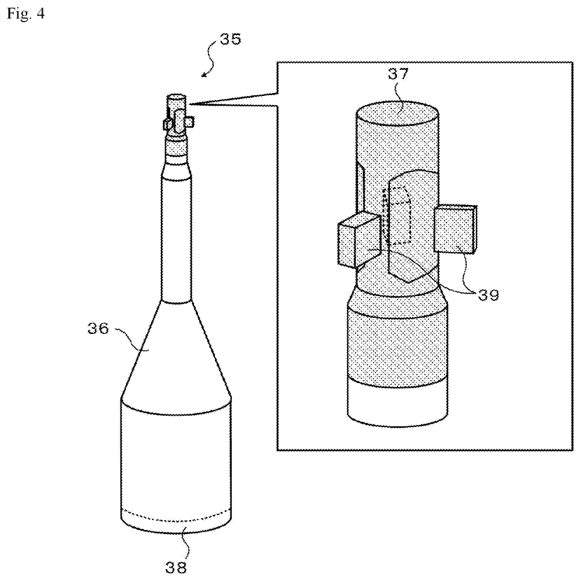

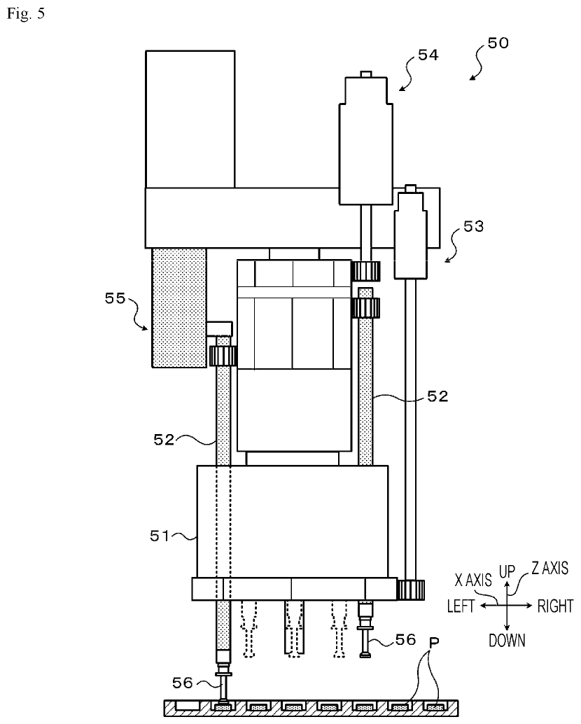

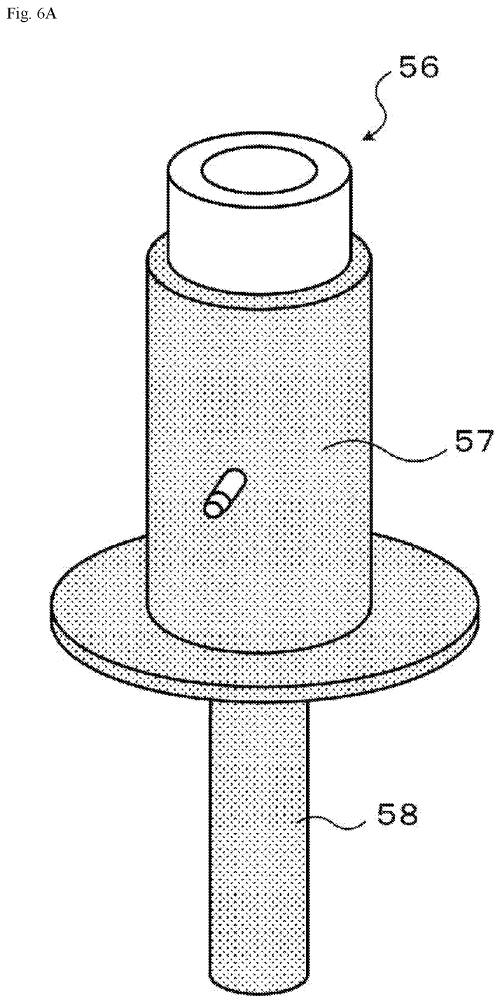

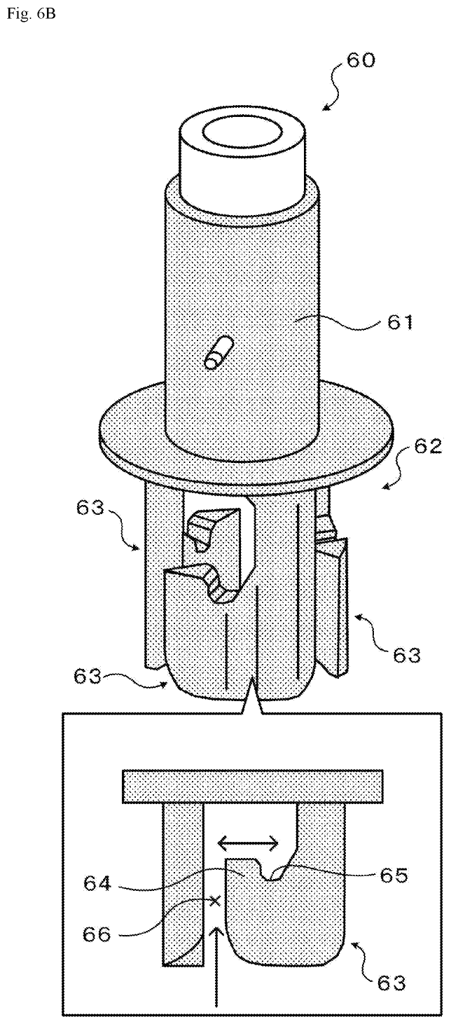

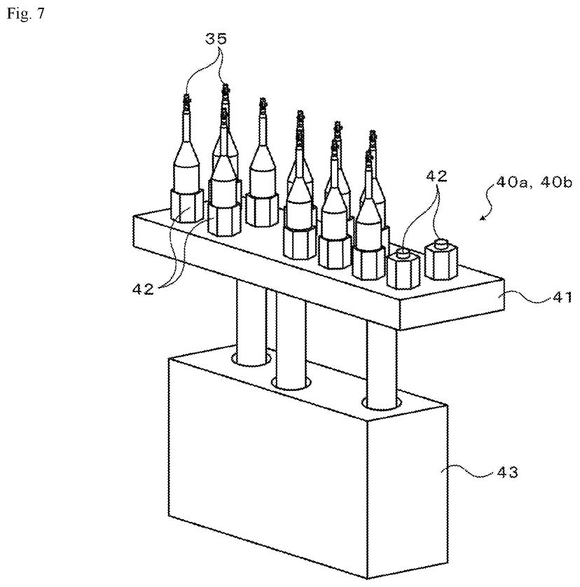

FIG. 1 is a schematic configuration view of a component mounter of the present embodiment. FIG. 2 is a block diagram illustrating an electrical coupling relationship of a component mounter. FIG. 3 is a schematic configuration view of a board conveyance device and a backup device. FIG. 4 is a schematic configuration view of a backup pin. FIG. 5 is a schematic configuration view of a head. FIG. 6A is a schematic configuration view of a suction nozzle. FIG. 6B is a schematic configuration view of a picker nozzle. FIG. 7 is a schematic configuration view of a backup pin stocker.

As illustrated in FIG. 1, component mounter 10 of the present embodiment includes feeder 16, board conveyance device 20, backup device 30, head 50, head movement device 70, and control device 90 (see FIG. 2). In addition to this, component mounter 10 also includes first backup pin stocker 40a and second backup pin stocker 40b, nozzle stocker 81, part camera 82, mark camera 83, and the like.

Feeder 16 is detachably attached to a feeder base (not illustrated) installed in a front portion of component mounter 10. Feeder 16 is, for example, a tape feeder and includes a carrier tape in which components are respectively accommodated in multiple cavities formed at predetermined intervals, a reel around which the carrier tape is wound, and a tape feeding device that unwinds and feeds the carrier tape from the reel.

As illustrated in FIG. 3, board conveyance device 20 is a belt conveyor device and is configured as a dual-lane type conveyance device including two lanes (first lane 20a and second lane 20b) that respectively convey board S from left to right in parallel.

As illustrated in FIG. 3, first lane 20a includes long fixing conveyor rail 21a extending in the left and right and long movement conveyor rail 22a that extends in the left and right and is movable in the front-rear direction. Each of fixing conveyor rail 21a and movement conveyor rail 22a includes side plate 23, pair of rollers 24 provided at both left and right end portions of a side surface of side plate 23 facing each other, conveyor belt 25 stretched over pair of rollers 24, belt drive device 26 (see FIG. 2) that drives conveyor belt 25 to rotate, and two support columns 27 that support both left and right end portions of side plate 23. Two support columns 27 of fixing conveyor rail 21a are fixed to a first end (front end portions in FIG. 3) of each of pair of left and right support bases 29 extending in the front-rear direction, and two support columns 27 of movement conveyor rail 22a are installed on guide rails 29g provided on support bases 29 so as to extend in the front-rear direction from the first end toward a second end. Movement conveyor rail 22a further includes rail movement device 28 and moves to the left and right along guide rail 29g by driving of rail movement device 28. First lane 20a can convey multiple types of boards S having different sizes by moving movement conveyor rail 22a according to a width of board S to adjust an interval between fixing conveyor rail 21a and movement conveyor rail 22a.

As illustrated in FIG. 3, second lane 20b includes long movement conveyor rail 21b that is installed adjacent to movement conveyor rail 22a of first lane 20a, extends in the left and right, and is movable in the front-rear direction, and long movement conveyor rail 22b that is installed adjacent to movement conveyor rail 21b on a side opposite to the movement conveyor rail 22a, extends in the left and right, and is movable in the front-rear direction. Each of movement conveyor rails 21b and 22b includes side plate 23, pair of rollers 24 provided at both left and right end portions of a side surface of side plate 23 facing each other, conveyor belt 25 stretched over pair of rollers 24, belt drive device 26 (see FIG. 2) that drives conveyor belt 25 to rotate, and two support columns 27 that support both left and right end portions of side plate 23. Two support columns 27 of movement conveyor rails 21b and 22b are installed on guide rail 29g common to first lane 20a. Movement conveyor rails 21b and 22b further include rail movement device 28 and move to the left and right along guide rail 29g by driving rail movement device 28. Second lane 20b can convey multiple types of boards S having different sizes by moving one or both of movement conveyor rails 21b and 22b according to a width of board S to adjust an interval therebetween.

As illustrated in FIG. 3, backup device 30 supports board S conveyed in each of first lane 20a and second lane 20b from a rear surface. Backup device 30 includes backup plate 31, plate lifting and lowering device 32 (see FIG. 2) that lifts and lowers backup plate 31, multiple backup pins 35 installed on backup plate 31, and first backup pin stocker 40a and second backup pin stocker 40b that accommodate unused extra backup pins 35. Backup plate 31 is a flat plate member that is formed of a magnetic material, extends in the front-rear direction, and has an installation surface on which backup pin 35 is installed on upper surface 31u. In the present embodiment, as illustrated in FIG. 3, board conveyance device 20 has two (multiple) lanes (first lane 20a and second lane 20b), and backup plate 31 extends such that both end portions in the front-rear direction span the multiple lanes. Thereby, by installing backup pins 35 required for one backup plate 31, board S conveyed in each of the two lanes can be backed up. However, the backup plate may be provided for each lane and may be configured to be lifted and lowered independently by separate plate lifting and lowering devices. Multiple through-holes 31h are formed in both end portions of backup plate 31 in the front-rear direction to vertically penetrate backup plate 31. Multiple through-holes 31h are arranged at predetermined intervals in the left-right direction (board conveyance direction) and each have an inner diameter through which one backup pin 35 can be inserted. Intervals between some of multiple through-holes 31h are formed such that backup pins 35 can be installed therebetween. Through-hole 31h may have an opening having an inner diameter greater than an inner diameter through which one backup pin 35 can be inserted. Plate lifting and lowering device 32 includes a ball screw device or an air cylinder device, and in a state where backup pins 35 are installed on an upper surface of backup plate 31, plate lifting and lowering device 32 lifts and lowers backup plate 31 between a position where a rear surface of board S and front ends of backup pins 35 are in contact with each other and a position where a rear surface of board S and the front ends of backup pins 35 are separated from each other.

As illustrated in FIG. 4, backup pin 35 includes pin body 36 that extends vertically in an upright state and has a front end portion having a diameter less than a diameter of a base end portion, flat support surface 37 formed at a front end of pin body 36, and permanent magnet 38 embedded in a bottom portion of pin body 36. Backup plate 31 is formed of a magnetic material as described above, and when backup pin 35 is installed on backup plate 31, backup pin 35 is fixed to backup plate 31 in an upright state by an attraction force due to magnetic force of permanent magnet 38. Further, multiple (three) engagement sections 39 (protrusion sections) protruding in a diameter direction at a predetermined angular interval (for example, 120°) in a circumferential direction are formed on an outer circumferential surface of a front end portion of backup pin 35.

As illustrated in FIG. 5, head 50 is, for example, a rotary head, and includes head body 51 in which multiple holders 52 are arranged in a circumferential direction, R-axis actuator 53 that rotates (revolves holders 52) head body 51, θ-axis actuator 54 that rotates (turns around on its axis) holders 52, and Z-axis actuator 55 that lifts and lowers holders 52. Suction nozzle 56 or picker nozzle 60 is exchangeably attached to a front end portion of holder 52.

As illustrated in FIG. 1, head movement device 70 includes pair of left and right Y-axis guide rails 73 provided on an upper end stage portion of housing 12 so as to extend in the front-rear direction, Y-axis slider 74 stretched over pair of Y-axis guide rails 73, X-axis guide rail 71 provided on Y-axis slider 74 so as to extend in the left and right, and X-axis slider 72 attached to X-axis guide rail 71. X-axis slider 72 is driven by X-axis actuator 75 (refer to FIG. 2), and Y-axis slider 74 is driven by Y-axis actuator 76 (refer to FIG. 2). Head 50 is attached to X-axis slider 72, and moves forward, backward, leftward, and rightward by driving X-axis actuator 75 and Y-axis actuator 76.

As illustrated in FIG. 6A, suction nozzle 56 includes attachment section 57 that is provided on a base end side and is inserted into and attached to holder 52, and picking section 58 that is provided on a front end side and picks a component. Picking section 58 is a cylindrical member, and sucks and picks a component by introducing a negative pressure from a negative pressure source (not illustrated).

Picker nozzle 60 is a nozzle capable of picking (picking up) backup pin 35 and, as illustrated in FIG. 6B, includes attachment section 61 formed in the same shape as above-described attachment section 57 to be attached to holder 52, and picking section 62 that is provided on a front end side and picks backup pin 35. Picking section 62 includes multiple (three) target engagement sections 63 that respectively engage with engagement sections 39 (protrusion sections) of backup pin 35. Multiple target engagement sections 63 are hook-shaped members including hook front end sections 64 and hook recess sections 65. Each of target engagement sections 63 is formed such that hook front end section 64 faces one side in a circumferential direction at a predetermined angular interval (for example, 120°) in the circumferential direction. Picker nozzle 60 picks backup pin 35 by inserting engagement section 39 (protrusion section) of backup pin 35 into gap 66 between target engagement sections 63 (hook sections) arranged in the circumferential direction and hanging engagement section 39 on hook recess section 65.

As illustrated in FIG. 1, nozzle stocker 81 is installed between first lane 20a and feeder 16, and accommodates multiple nozzles for exchange. In the present embodiment, nozzle stocker 81 accommodates multiple types of suction nozzles 56 having different sizes, and also accommodates above-described picker nozzle 60. The nozzles attached to holder 52 are automatically exchanged as necessary based on the movement of head 50 by head movement device 70 and lifting and lowering of holder 52 by Z-axis actuator 55 with respect to nozzle stocker 81.

First backup pin stocker 40a and second backup pin stocker 40b accommodate multiple backup pins 35. As illustrated in FIG. 3, first backup pin stocker 40a is disposed under multiple through-holes 31h formed in the front end portion of backup plate 31, and accommodates backup pins 35 installed in first lane 20a (between fixing conveyor rail 21a and movement conveyor rail 22a) of backup plate 31. Meanwhile, second backup pin stocker 40b is disposed under multiple through-holes 31h formed in a rear end portion of backup plate 31, and accommodates backup pins 35 installed in second lane 20b (between movement conveyor rails 21b and 22b) of backup plate 31. In this way, by installing first backup pin stocker 40a and second backup pin stocker 40b under backup plate 31 (in backup device 30), feeder 16 can be brought closer to board conveyance device 20 than when installed outside backup device 30. Accordingly, it is possible to reduce a movement distance of head 50 when a component is picked from feeder 16 and mounted on board S and to reduce mounting time.

As illustrated in FIG. 7, each of first backup pin stocker 40a and second backup pin stocker 40b includes accommodation base 41 and accommodation base lifting and lowering device 43 that lifts and lowers accommodation base 41. Multiple accommodation protrusions 42 are provided on an upper surface of accommodation base 41 and are located directly under respectively corresponding through-holes 31h. In the present embodiment, accommodation protrusion 42 is formed of a magnetic material. Backup pin 35, when placed on accommodation protrusion 42, is fixed to accommodation protrusion 42 in an upright state by attraction force due to magnetic force of permanent magnet 38 embedded in a bottom portion.

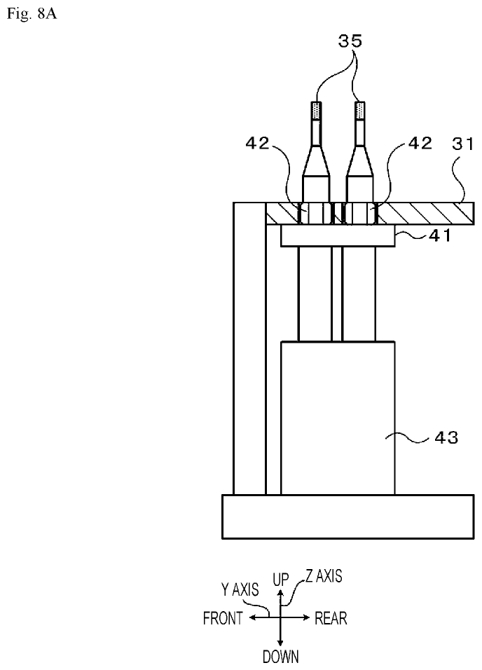

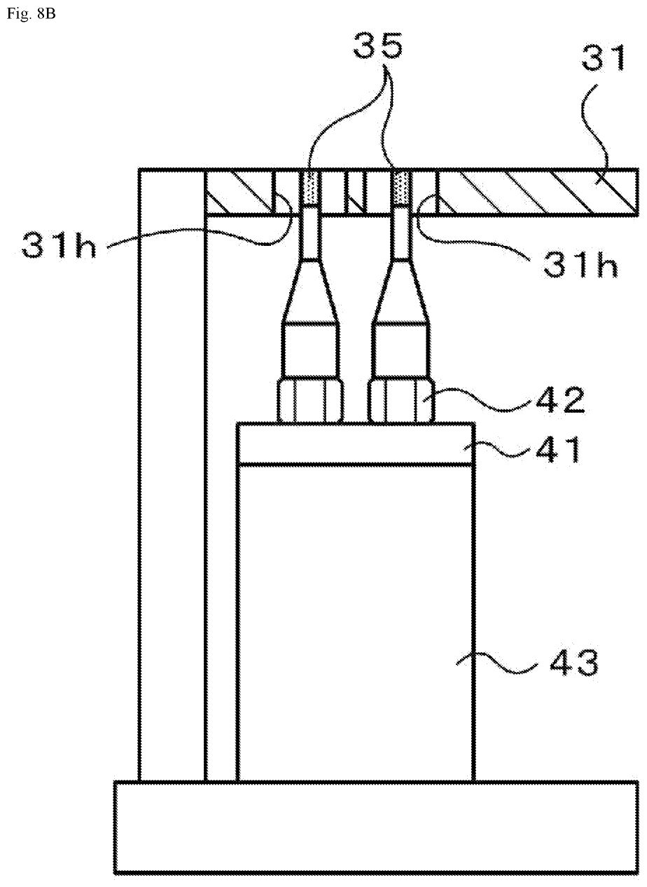

Accommodation base lifting and lowering device 43 includes an air cylinder device or a ball screw device, and lifts and lowers accommodation base 41 between a position where an upper surface of accommodation base 41 is in contact with a bottom surface of backup plate 31 and a position where the upper surface of accommodation base 41 is separated from the bottom surface of backup plate 31. Accommodation protrusion 42 has substantially the same height as a thickness of backup plate 31, and as accommodation base 41 lifts to a lifting end, backup pin 35 placed on accommodation protrusion 42 lifts until the bottom surface of backup pin 35 is at substantially the same height as the upper surface of backup plate 31, as illustrated in FIG. 8A. In addition, as accommodation base 41 is lowered to a lowering end, backup pin 35 placed on accommodation protrusion 42 is lowered until some or all of backup pins 35 are located under backup plate 31, as illustrated in FIG. 8B.

As illustrated in FIG. 2, control device 90 includes CPU 91, ROM 92, RAM 93, storage device 94, and input/output interface 95. These are electrically coupled to each other via bus 96. Various signals from an X-axis position sensor that detects a position of X-axis slider 72, a Y-axis position sensor that detects a position of Y-axis slider 74, a Z-axis position sensor that detects a lifting and lowering position of holder 52, part camera 82, mark camera 83, and the like are input to control device 90 via input/output interface 95. Meanwhile, various control signals to feeder 16, belt drive device 26, rail movement device 28, plate lifting and lowering device 32, accommodation base lifting and lowering device 43, X-axis actuator 75, Y-axis actuator 76, R-axis actuator 53, θ-axis actuator 54, Z-axis actuator 55, part camera 82, mark camera 83, and the like are output from control device 90 via input/output interface 95. Control device 90 is communicably coupled to a management computer (not illustrated), receives a job from the management computer, and produces a product in which components are mounted on board S according to the received job.

Part camera 82 is installed between first lane 20a and feeder 16, images a component picked by suction nozzle 56 from below, and transmits the image to control device 90. Control device 90 recognizes a pickup error or a pickup deviation by processing the captured image.

Mark camera 83 is installed on head 50 or X-axis slider 72, images a reference mark attached to board S from above, or images backup pin 35 on backup plate 31 from above, and transmits the captured image to control device 90. Control device 90 recognizes a position of board S or a position of backup pin 35 by processing the captured image.

Next, an operation of component mounter 10 of the present embodiment configured as described above will be described. First, a mounting operation of picking a component from feeder 16 and mounting the components on board S will be described. CPU 91 of control device 90 first controls board conveyance device 20 (first lane 20a or second lane 20b) to carry board S into a machine. Subsequently, CPU 91 supports board S carried in by lifting backup plate 31 on plate lifting and lowering device 32 by using backup pins 35 installed on backup plate 31. Next, CPU 91 causes head movement device 70 to move head 50 above a component supply position of feeder 16, lowers suction nozzle 56 by Z-axis actuator 55, and picks the component supplied to the component supply position. When picking the component, CPU 91 causes head movement device 70 to move the picked component above part camera 82, and causes part camera 82 to image the component. Next, CPU 91 processes the captured image to measure a pickup deviation of the component, and corrects a mounting position of the component on board S. Then, CPU 91 causes head movement device 70 to move the picked component above the corrected mounting position, and lowers suction nozzle 56 by Z-axis actuator 55 to mount the component on board S.

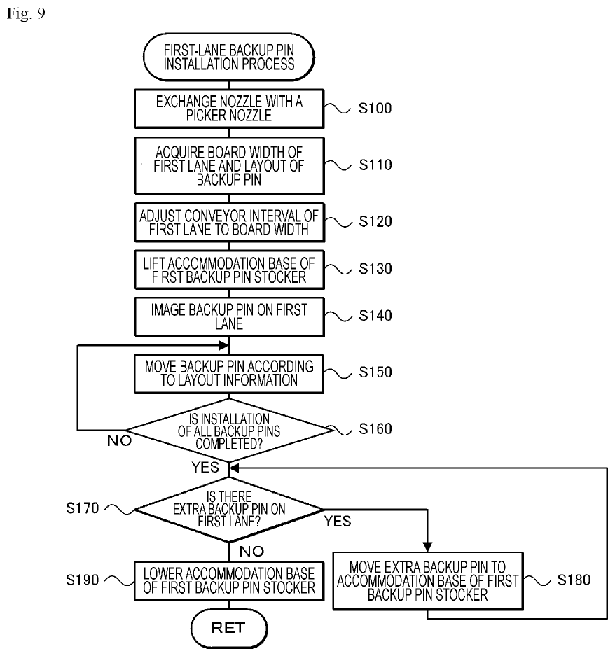

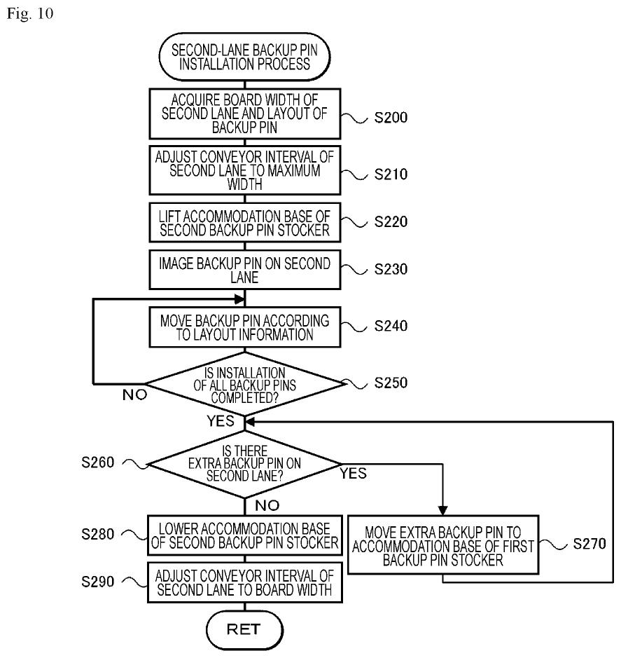

Next, an operation when backup pins 35 are automatically installed on backup plate 31 before the start of production will be described. FIG. 9 is a flowchart illustrating an example of a first-lane backup pin installation process. FIG. 10 is a flowchart illustrating an example of a second-lane backup pin installation process. A first-lane backup pin installation process is performed when an instruction for a setup change is received from a management computer, and a second-lane backup pin installation process is performed after the first-lane backup pin installation process is performed. Hereinafter, the first-lane backup pin installation process and the second-lane backup pin installation process will be subsequently described.

In the first-lane backup pin installation process, CPU 91 first causes head movement device 70 to move head 50 above nozzle stocker 81, and exchanges a nozzle attached to holder 52 with picker nozzle 60 (step S100). Subsequently, CPU 91 acquires width information of board S to be conveyed in first lane 20a and layout information of backup pins 35 from the management computer (step S110). Then, CPU 91 causes rail movement device 28 to move movement conveyor rail 22a based on the acquired width information of board S to adjust an interval between fixing conveyor rail 21a and movement conveyor rail 22a of first lane 20a to a board width (step S120).

Next, CPU 91 causes accommodation base lifting and lowering device 43 to lift accommodation base 41 of first backup pin stocker 40a (step S130), and causes mark camera 83 to image first lane 20a side of backup plate 31 (step S140). Subsequently, CPU 91 recognizes a position of backup pin 35 installed in first lane 20a by processing the captured image, and moves backup pin 35 according to the layout information received in step S110 (step S150). Here, backup pin 35 is moved as follows. That is, CPU 91 first causes head movement device 70 to move picker nozzle 60 directly above backup pin 35 of a movement target. Next, CPU 91 causes θ-axis actuator 54 to adjust a phase of picker nozzle 60 such that gap 66 between target engagement sections 63 (hook sections) in a circumferential direction of picker nozzle 60 is located directly above engagement section 39 (protrusion section) of backup pin 35, and causes Z-axis actuator 55 to lower picker nozzle 60 until engagement section 39 enters gap 66 and exceeds hook front end section 64. Then, CPU 91 causes θ-axis actuator 54 to adjust a phase of picker nozzle 60 such that engagement section 39 is located directly above hook recess section 65, and causes Z-axis actuator 55 to lift picker nozzle 60. Thereby, backup pins 35 are picked by fitting engagement section 39 (protrusion section) into hook recess section 65 of picker nozzle 60.

When backup pins 35 are moved, CPU 91 determines whether installation of all backup pins 35 in first lane 20a is completed (step S160). When it is determined that the installation of all backup pins 35 of first lane 20a is not completed, the process returns to step S150, and CPU 91 moves backup pin 35 of a next movement target according to the layout information.

When it is determined in step S160 that the installation of all backup pins 35 of first lane 20a is completed, CPU 91 determines whether there is an extra backup pin 35 on first lane 20a (step S170). When it is determined that there is an extra backup pin 35, CPU 91 moves backup pin 35 to accommodation base 41 of first backup pin stocker 40a (step S180). This process is performed by checking an empty situation of accommodation protrusion 42 of first backup pin stocker 40a based on the captured image obtained in step S140, picking backup pin 35 of a movement target, inserting backup pin 35 through through-hole 31h, and placing backup pin 35 on empty accommodation protrusion 42.

When it is determined in step S170 that there is no extra backup pin 35 on first lane 20a, CPU 91 causes accommodation base lifting and lowering device 43 to lower accommodation base 41 of first backup pin stocker 40a (step S190), and ends the first-lane backup pin installation process.

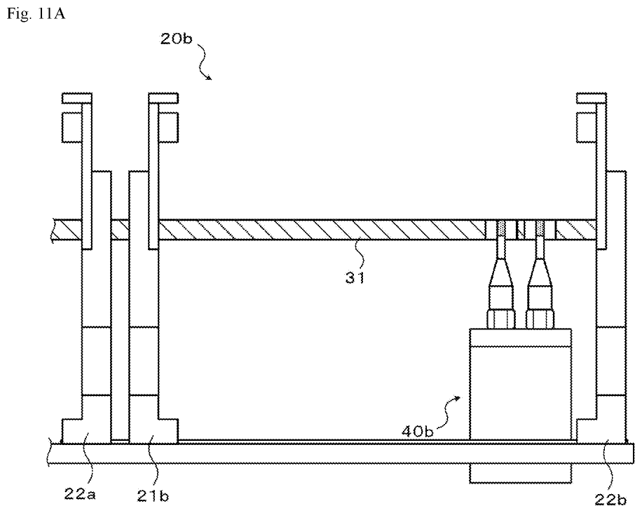

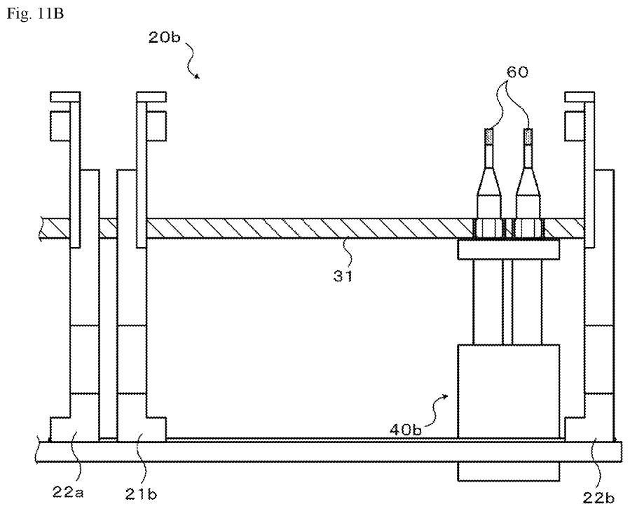

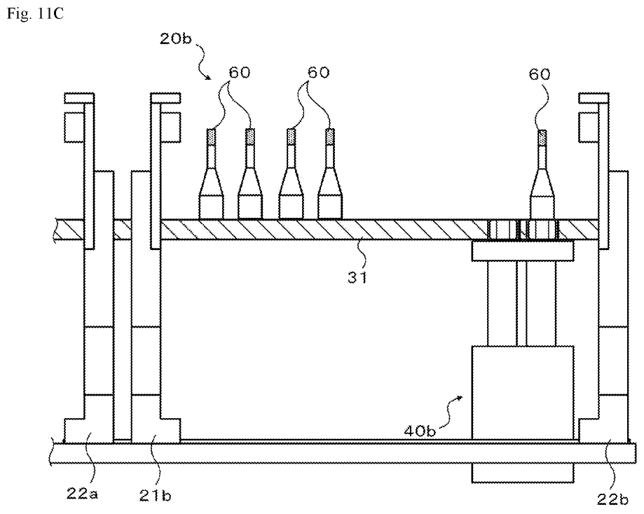

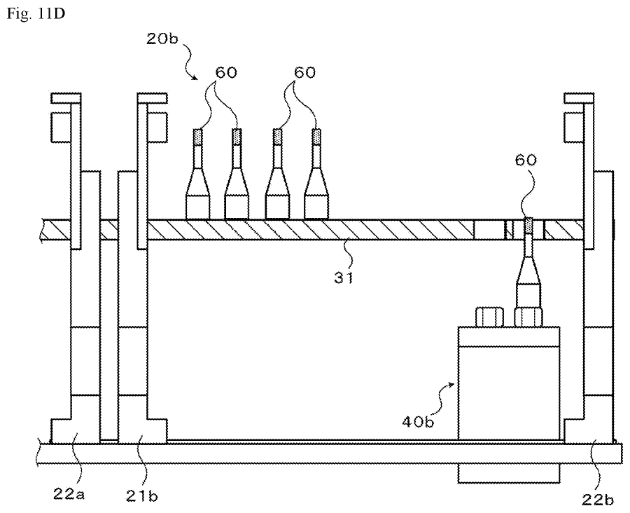

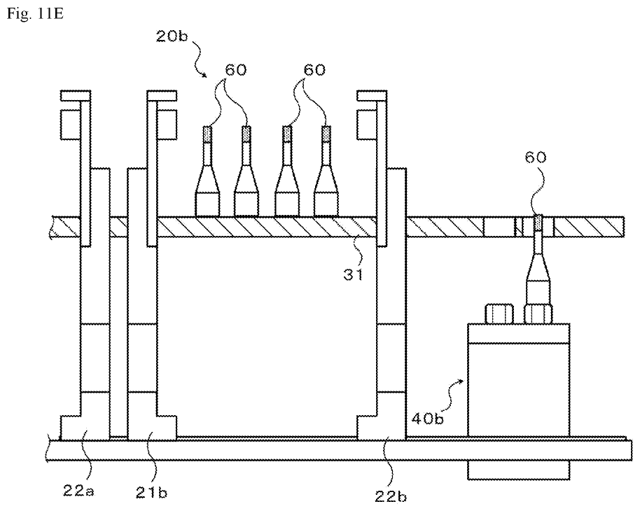

Next, the second-lane backup pin installation process will be described with reference to FIGS. 11A to 11E. In the second-lane backup pin installation process, CPU 91 first acquires width information of board S conveyed in second lane 20b and layout information of backup pin 35 from a management computer (step S200). Subsequently, CPU 91 causes rail movement device 28 to move movement conveyor rails 21b and 22b of second lane 20b to adjust an interval therebetween to a maximum width (step S210). This process is performed by moving movement conveyor rail 21b to a position close to movement conveyor rail 22a of first lane 20a and moving movement conveyor rail 22b to a position behind second backup pin stocker 40b (see FIG. 11A).

Next, CPU 91 lifts accommodation base 41 of second backup pin stocker 40b by accommodation base lifting and lowering device 43 (step S220, see FIG. 11B), and causes mark camera 83 to image second lane 20b side of backup plate 31 (step S230). Subsequently, CPU 91 recognizes a position of backup pin 35 installed in second lane 20b by processing the captured image, and moves the backup pin 35 according to the layout information received in step S200 (step S240, see FIG. 11C).

When backup pin 35 is moved, CPU 91 determines whether installation of all backup pins 35 in second lane 20b is completed (step S250). When it is determined that the installation of all backup pins 35 of second lane 20b is not completed, the process returns to step S240 and CPU 91 moves backup pin 35 of a next movement target according to the layout information.

When it is determined in step S250 that the installation of all backup pins 35 of second lane 20b is completed, CPU 91 determines whether there is extra backup pin 35 on second lane 20b (step S260). When it is determined that there is extra backup pin 35, CPU 91 moves backup pin 35 to accommodation base 41 of second backup pin stocker 40b (step S270).

When it is determined in step S260 that there is no extra backup pin 35 on second lane 20b, CPU 91 causes accommodation base lifting and lowering device 43 to lower accommodation base 41 of second backup pin stocker 40b (step S290, see FIG. 11D). Then, CPU 91 causes rail movement device 28 to move movement conveyor rail 22b based on the width information of board S acquired in step S200 to adjust an interval between movement conveyor rail 21b and movement conveyor rail 22b of second lane 20b to a board width (step S290, see FIG. 11E), and ends the second-lane backup pin installation process.

Here, a correspondence relationship between main elements of the embodiment and main elements of the present disclosure described in the claims will be described. That is, head 50 of the present embodiment corresponds to the head of the present disclosure, board conveyance device 20 (first lane 20a and second lane 20b) corresponds to a board conveyance device, backup pin 35 corresponds to a backup pin, through-hole 31h corresponds to a through-hole, backup plate 31 corresponds to a backup plate, and accommodation base 41 corresponds to an accommodation base. Fixing conveyor rail 21a and movement conveyor rail 22a correspond to a pair of conveyor rails. Accommodation base lifting and lowering device 43 corresponds to an accommodation base lifting and lowering device. Holder 52 corresponds to a holder, and Z-axis actuator 55 corresponds to a holder lifting and lowering device. In addition, control device 90 corresponds to a control device.

It is needless to say that the present disclosure is not limited to the embodiments described above in any way and can be implemented in various aspects as long as the aspects fall within the technical scope of the present disclosure.

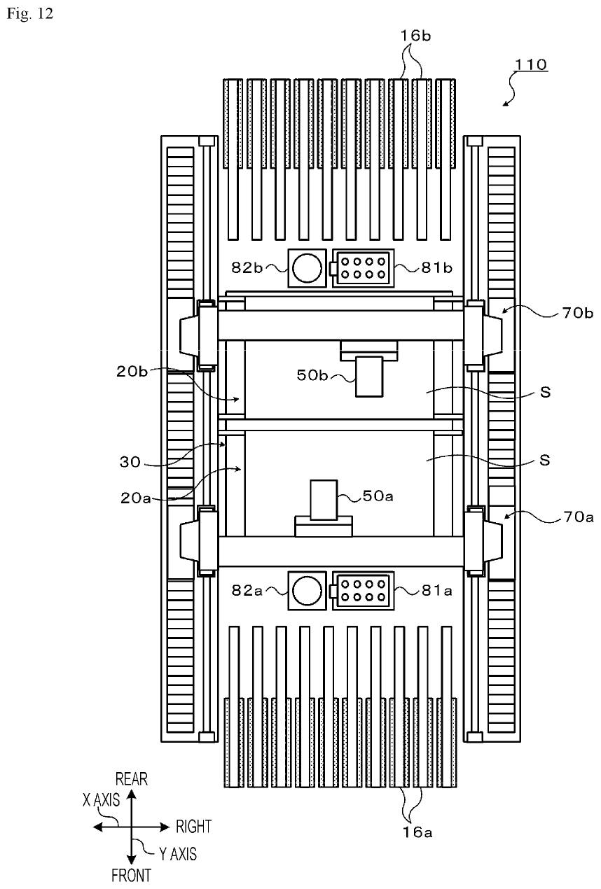

For example, in the embodiment described above, component mounter 10 includes one head 50 capable of picking components and mounting components on board S but may include multiple heads capable of picking components, mounting the components on board S, and independently moving each other. FIG. 12 is a schematic configuration view of component mounter 110 according to another embodiment. Component mounter 110 includes two feeder sets (first feeder 16a and second feeder 16b), board conveyance device 20 (first lane 20a and second lane 20b) that is the same as in the present embodiment, backup device 30, two heads (first head 50a and second head 50b), and two head movement devices (first head movement device 70a and second head movement device 70b) that independently move the two heads. First feeder 16a is attached to a feeder base provided in a front portion of component mounter 110, and second feeder 16b is attached to a feeder base provided in a rear portion of component mounter 110. In addition, first nozzle stocker 81a and first part camera 82a are installed between first lane 20a and first feeder 16a, and second nozzle stocker 81b and second part camera 82b are installed between second lane 20b and second feeder 16b. Boards S carried into each of first lane 20a and second lane 20b are backed up by backup pins of backup device 30. Further, as in the present embodiment, the extra backup pins are accommodated in a backup pin stocker (not illustrated) provided in backup device 30.

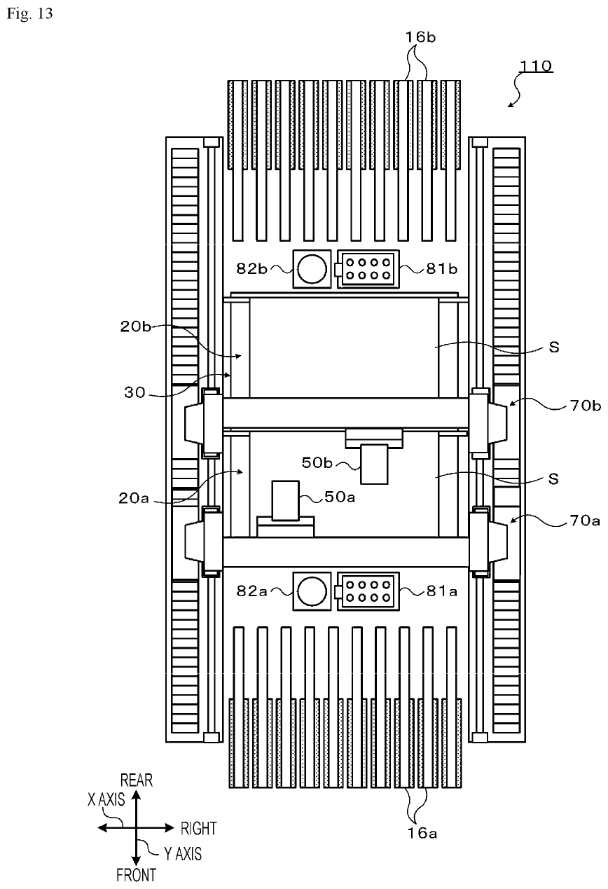

In component mounter 110 configured as described above, first head 50a mounts a component on board S carried into first lane 20a, and second head 50b mounts a component on board S carried into second lane 20b. That is, as illustrated in FIG. 13, first head 50a picks a component supplied from first feeder 16a, and moves the component above first part camera 82a. Then, first head 50a causes first part camera 82a to image the picked component, and then mounts the component on board S carried into first lane 20a. Second head 50b picks a component supplied from second feeder 16b and moves the component above second part camera 82b. Then, second head 50b causes second part camera 82b to image the picked component, and then mounts the component on board S carried into second lane 20b.

In addition, in component mounter 110, first head 50a and second head 50b may cooperate to mount a component on board S carried into first lane 20a. That is, as illustrated in FIG. 13, first head 50a picks the component supplied from first feeder 16a, and moves the component above first part camera 82a. Then, first head 50a causes first part camera 82a to image the picked component, and then mounts the component on board S carried into first lane 20a. Second head 50b picks a component supplied from second feeder 16b and moves the component above second part camera 82b. Then, second head 50b causes second part camera 82b to image the picked component, and then mounts the component on board S carried into first lane 20a. First head 50a and second head 50b may alternately mount components on same board S such that first head 50a and second head 50b do not interfere with each other.

In the embodiment described above, first lane 20a includes fixing conveyor rail 21a and movement conveyor rail 22a, and second lane 20b includes two movement conveyor rails 21b and 22b. However, both the first lane and the second lane may be configured with two movement conveyor rails or may be configured with one fixing conveyor rail and one movement conveyor rail. In the latter case, the first lane and the second lane may be installed such that respective conveyor rails are arranged in the order of a movement conveyor rail, a fixing conveyor rail, a fixing conveyor rail, and a movement conveyor rail in a front-rear (Y axis) direction, or may be installed such that the respective conveyor rails are arranged in the order of the fixing conveyor rail, the movement conveyor rail, the movement conveyor rail, and the fixing conveyor rail.

As described above, the component mounter of the present disclosure can accommodate backup pins 35 under backup plate 31, and thus, it is not necessary to secure a dedicated space for accommodating backup pins 35. As a result, unused backup pins 35 can be accommodated in a device while preventing an increase in size of backup device 30.

In the component mounter of the present disclosure, a through-hole may include multiple through-holes through which backup pins can be respectively inserted. Accordingly, it is possible to reduce an area of a through-hole and enlarge an installation surface of a backup pin on a backup plate.

In addition, in the component mounter of the present disclosure, a board conveyance device may include a pair of conveyor rails that convey the board, a first one of the pair of conveyor rails may be a fixing side conveyor rail that is fixed, a second one of the pair of conveyor rails may be a movable movement side conveyor rail so as to approach and separate from the one conveyor rail in a direction orthogonal to a board conveyance direction, and the through-hole may be formed near the fixing side conveyor rail on the backup plate. Accordingly, a backup pin can be carried into and out of an accommodation base regardless of a position of a movement conveyor rail.

Further, the component mounter of the present disclosure may further include an accommodation base lifting and lowering device that lifts and lowers the accommodation base. In this case, the accommodation base lifting and lowering device may lift the backup pin placed on the accommodation base until a bottom surface of the backup pin is at substantially the same height as the installation surface of the backup plate. Accordingly, a backup pin can be easily carried into and out of an accommodation base.

In addition, in the component mounter of the present disclosure, the backup pin may include a permanent magnet on a bottom surface so as to be picked up and fixed to the backup plate and the accommodation base by a magnetic attraction force. Accordingly, a backup pin can be easily fixed to a backup plate or an accommodation base with a simple configuration.

In addition, in the component mounter of the present disclosure, the head may include a holder and a holder lifting and lowering device that lifts and lowers the holder, and a component picking member capable of picking the component and a pin picking member capable of picking the backup pin may be detachably attached to the holder. Accordingly, a head can be made more compact and costs can be reduced compared to a head including a dedicated holding member for holding a pin picking member.

In addition, in the component mounter of the present disclosure, the board conveyance device may include a first pair of conveyor rails and a second pair of conveyor rails that convey boards in parallel with each other and may be arranged in an orthogonal direction orthogonal to a board conveyance direction, at least one conveyor rail among the second pair of conveyor rails may be a movement side conveyor rail that is movable in the orthogonal direction orthogonal to the board conveyance direction, and the through-hole may be formed near the movement side conveyor rail on the backup plate. In this case, the component mounter may further include a control device that controls movement of the head and movement of the movement side conveyor rail, and the head may be capable of picking the backup pin, and the control device may move the movement side conveyor rail such that the through-hole is located between the second pair of conveyor rails, and then take out the backup pin placed on the accommodation base under the through-hole by using the head to install the backup pin at a necessary position between the second pair of conveyor rails on the backup plate, and move the movement side conveyor rail such that an interval between the second pair of conveyor rails becomes an interval according to a board to be conveyed. Accordingly, regardless of a size of a board to be conveyed, a necessary backup pin can be taken out from an accommodation base and installed at a necessary position between a second pair of conveyor rails on a backup plate.

In addition, in the component mounter of an aspect of the present disclosure including the first and second pair of conveyor rails, the head may include a first head and a second head which are independently movable, the first head may be capable of mounting the component on the board conveyed by the first pair of conveyor rails, and the second head may be capable of mounting the component on the board conveyed by the second pair of conveyor rails.

In addition, in the component mounter of an aspect of the present disclosure including the first and second pair of conveyor rails, the head may include a first head and a second head which are independently movable, and at least one of the first head and the second head may be capable of mounting components respectively on both boards conveyed by the first pair of conveyor rails and the second pair of conveyor rails.

The present disclosure is not limited to the form of a component mounter, and can be implemented in a form of a backup pin accommodation method.

### INDUSTRIAL APPLICABILITY

The present disclosure can be used for a manufacturing industry of component mounters, and the like.

### REFERENCE SIGNS LIST

10,110 component mounter, 12 housing, 16 feeder, 16a first feeder, 16b second feeder, 20 board conveyance device, 20a first lane, 20b second lane, 21a fixing conveyor rail, 21b movement conveyor rail, 22a movement conveyor rail, 22b movement conveyor rail, 23 side plate, 24 roller, 25 conveyor belt, 26 belt drive device, 27 support column, 28 rail movement device, 29 support base, 29g guide rail, 30 backup device, 31 backup plate, 31u upper surface, 31h through-hole, 32 plate lifting and lowering device, 35 backup pin, 36 pin body, 37 support surface, 38 permanent magnet, 39 engagement section, 40a first backup pin stocker, 40b second backup pin stocker, 41 accommodation base, 42 accommodation protrusion, 43 accommodation base lifting and lowering device, 50 head, 50a first head, 50b second head, 51 head body, 52 holder, 53 R-axis actuator, 54 θ-axis actuator, 55 Z-axis actuator, 56 suction nozzle, 57 attachment section, 58 picking section, 60 picker nozzle, 61 attachment section, 62 picking section, 63 target engagement section, 64 hook front end section, 65 hook recess section, 66 gap, 70 head movement device, 70a first head movement device, 70b second head movement device, 71 X-axis guide rail, 72 X-axis slider, 73 Y-axis guide rail, 74 Y-axis slider, 75 X-axis actuator, 76 Y-axis actuator, 81 nozzle stocker, 81a first nozzle stocker, 81b second nozzle stocker, 82 part camera, 82a first part camera, 82b second part camera, 83 mark camera, 90 control device, 91 CPU, 92 ROM, 93 RAM, 94 storage device, 95 input/output interface, 96 bus, S board

1. A component mounter for mounting a component on a board, comprising:
a head configured to pick the component;
a board conveyance device configured to convey the board;
a backup device including a backup pin and a backup plate having an installation surface on which the backup pin is installed and a through-hole penetrating the backup plate vertically such that the backup pin can be inserted, and configured to back up the board conveyed by the board conveyance device from a rear surface by using the backup pin installed on the installation surface; and
an accommodation base which is disposed to be located under the through-hole and on which the backup pin inserted through the through-hole is placed.

2. The component mounter according to claim 1, wherein
the through-hole includes multiple through-holes through which backup pins can be respectively inserted.

3. The component mounter according to claim 1, wherein
the board conveyance device includes a pair of conveyor rails configured to convey the board,
a first one of the pair of conveyor rails is a fixing side conveyor rail that is fixed,
a second one of the pair of conveyor rails is a movement side conveyor rail that is movable so as to approach and separate from the first one of the conveyor rails in an orthogonal direction orthogonal to a board conveyance direction, and
the through-hole is formed near the fixing side conveyor rail on the backup plate.

4. The component mounter according to claim 1, further comprising:
an accommodation base lifting and lowering device configured to lift and lower the accommodation base.

5. The component mounter according to claim 4, wherein
the accommodation base lifting and lowering device lifts the backup pin placed on the accommodation base until a bottom surface of the backup pin is at substantially the same height as the installation surface of the backup plate.

6. The component mounter according to claim 1, wherein
the backup pin includes a permanent magnet on a bottom surface so as to be attracted and fixed to the backup plate and the accommodation base by a magnetic attraction force.

7. The component mounter according to claim 1, wherein
the head includes a holder and a holder lifting and lowering device configured to lift and lower the holder, and
a component picking member capable of picking the component and a pin picking member capable of picking the backup pin are detachably attached to the holder.

8. The component mounter according to claim 1, wherein
the board conveyance device includes a first pair of conveyor rails and a second pair of conveyor rails that are configured to convey boards in parallel with each other and are arranged in an orthogonal direction orthogonal to a board conveyance direction,
at least one conveyor rail among the second pair of conveyor rails is a movement side conveyor rail that is movable in the orthogonal direction orthogonal to the board conveyance direction, and
the through-hole is formed near the movement side conveyor rail on the backup plate.

9. The component mounter according to claim 8, further comprising:
a control device configured to control movement of the head and movement of the movement side conveyor rail,
the head is capable of picking the backup pin, and
the control device moves the movement side conveyor rail such that the through-hole is located between the second pair of conveyor rails, and then takes out the backup pin placed on the accommodation base under the through-hole by using the head to install the backup pin at a necessary position between the second pair of conveyor rails on the backup plate, and moves the movement side conveyor rail such that an interval between the second pair of conveyor rails becomes an interval corresponding to a board to be conveyed.

10. The component mounter according to claim 8, wherein
the head includes a first head and a second head which are independently movable,
the first head is capable of mounting the component on the board conveyed by the first pair of conveyor rails, and
the second head is capable of mounting the component on the board conveyed by the second pair of conveyor rails.

11. The component mounter according to claim 8, wherein
the head includes a first head and a second head which are independently movable, and
at least one of the first head and the second head is capable of mounting components respectively on both boards conveyed by the first pair of conveyor rails and the second pair of conveyor rails.

12. An accommodation method of accommodating unused backup pins in a backup device configured to back up a board from a rear surface by using a backup pin installed on a backup plate, the accommodation method comprising:
inserting the backup pin through a through-hole formed to vertically penetrate the backup plate, and placing the backup pin inserted through the through-hole on an accommodation base disposed under the through-hole.
